(19) United States
(12) Patent Application Publication
(10) Pub. No.: US 2020/0381574 A1
(43) Pub. Date: Dec. 3, 2020

(54) OPTICAL SENSING CHIP PACKAGING STRUCTURE

(71) Applicant: TAIWAN ELECTRONIC PACKAGING CO., LTD., Zhubei City (TW)

(72) Inventor: CHERNG-CHIAO WU, Zhubei City (TW)

(73) Assignee: TAIWAN ELECTRONIC PACKAGING CO., LTD., Zhubei City (TW)

(21) Appl. No.: 16/570,288

(22) Filed: Sep. 13, 2019

(30) Foreign Application Priority Data
May 31, 2019 (TW) 108119002

(51) Int. Cl. H01L 31/12; H01L 31/18; H01L 31/0203; H01L 31/0232

(52) U.S. Cl. CPC H01L 31/12; H01L 31/0232; H01L 31/0203; H01L 31/18

(57) ABSTRACT

An optical sensing chip packaging structure includes a substrate, an optical sensing member, a light emitting member, a transparent glue layer and a transparent cover plate, wherein the optical sensing member is positioned on the substrate; the light emitting member is positioned on the optical sensing member, and the light emitting member includes a light emitting surface; the transparent glue layer is positioned on the light emitting member, and contacts and covers the light emitting surface; the transparent cover plate is positioned on the transparent glue layer.

### BACKGROUND OF THE INVENTION

### 1. Technical Field

The present invention is related to a chip packaging structure, and more particularly to an optical sensing chip packaging structure.

### 2. Description of Related Art

FIG. 1 is a cross-sectional view of a conventional optical sensing chip packaging structure 100, which is composed of a substrate 120, an optical sensing member 140 and a light emitting member 160, wherein the light emitting member 160 is separated from the substrate 120 and the optical sensing member 140. The optical sensing member 140 is positioned on the substrate 120. The light emitting member 160 is used to emit a light toward an object O, and the light would be reflected by the object O and would go to the optical sensing member 140, whereby said optical sensing chip packaging structure 100 could be used to sense whether the object O is positioned in front of the optical sensing chip packaging structure 100; or, the optical sensing chip packaging structure 100 could be used to detect a movement of the object O relative to the optical sensing chip packaging structure 100. Therefore, the optical sensing chip packaging structure 100 could be used as an optical ruler or a servo motor. However, the optical sensing member 140 of the optical sensing chip packaging structure 100 is directly exposed outside, and therefore, the optical sensing member 140 is easy to be contaminated by dust or dirt, so that the sensing result of the optical sensing member 140 would be inaccurate.

For solving the above issue, another conventional optical sensing chip packaging structure 200, which is composed of a substrate 220, an optical sensing member 240, a light emitting member 260 and a transparent cover plate 280, as shown in FIG. 1. The optical sensing member 240 is positioned on the substrate 220; the light emitting member 260 is positioned on the optical sensing member 240; the transparent cover plate 280 is positioned on the light emitting member 260, which is used to protect the optical sensing member 240 and the light emitting member 260. Different from the optical sensing chip packaging structure 100, the optical sensing chip packaging structure 200 has an integral structure, in which the substrate 220, the optical sensing member 240, the light emitting member 260 and the transparent cover plate 280 are integrated together, in order to reduce the volume of the optical sensing chip packaging structure 200 and improve an optical sensing path; at the same time, the optical sensing chip packaging structure 200 could prevent the optical sensing member 240 and the light emitting member 260 from being contaminated by dust or dirt.

However, there is an air gap 270 between the transparent cover plate 280 and the light emitting member 260; when a light L emitting from the light emitting member 260, the light L would be refracted and reflected significantly at the interface between the gap 270 and the transparent cover plate 280, whereby to lose the light energy. Furthermore, a reflected light R (from the light L) would go into the optical sensing member 240 to result significant signals, whereby to reduce a resolution and a accuracy of the conventional optical sensing chip packaging structure 200.

At least for the above reasons, the conventional optical sensing chip packaging structure 100, 200 still has room for improvements.

### BRIEF SUMMARY OF THE INVENTION

In view of the above, the primary objective of the present invention is to provide an optical sensing chip packaging structure, which includes a transparent glue layer positioned between the light emitting member and the transparent cover plate, and the transparent glue layer contacts the light emitting member, which could reduce the loss of the light energy, and could prevent the optical sensing member and the light emitting member from being contaminated by dust.

The present invention provides an optical sensing chip packaging structure includes a substrate, an optical sensing member, a light emitting member, a transparent glue layer, a transparent cover plate. The optical sensing member is positioned on and is electrically connected to the substrate. The light emitting member is positioned on the optical sensing member, and is electrically connected to the substrate or the optical sensing member, wherein the light emitting member has a light emitting surface. The transparent glue layer is positioned on the light emitting member, and contacts and covers the light emitting surface. The transparent cover plate is positioned on the transparent glue layer, wherein the transparent cover plate contacts the transparent glue layer.

Another objective of the present invention is to provide an optical sensing chip packaging structure, which includes a substrate, an optical sensing member, a light emitting member, a transparent focusing lens and a transparent cover plate. The optical sensing member is positioned on and is electrically connected to the substrate. The light emitting member is positioned on the optical sensing member, and is electrically connected to the substrate or the optical sensing member, wherein the light emitting member has a light emitting surface. The transparent focusing lens is positioned on the light emitting member, and contacts and covers the light emitting surface. The transparent cover plate is positioned on the transparent focusing lens.

With the aforementioned design, the transparent glue layer contacts the light emitting surface of the light emitting member, and contacts the transparent cover plate, wherein the light is emitted from the light emitting surface through the transparent glue layer and the transparent cover plate, and there is no air gap between the transparent glue layer and the transparent cover plate, so that the light reflection of the transparent cover plate could be reduced, and the light energy loss by refraction could be reduced. In addition, while the transparent focusing lens is positioned on the light emitting member, and contacts and covers the light emitting surface, it could prevent the light emitting surface of the light emitting member from be covered by dust or dirt in air. Further, the transparent focusing lens is used to make scattered lights from the light emitting member changing to parallel lights, whereby to reduce the light noise and to reduce the light energy loss.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a cross-sectional view of a conventional optical sensing chip packaging structure;

FIG. 2 is a cross-sectional view of another conventional optical sensing chip packaging structure;

FIG. 3 is a cross-sectional view of an optical sensing chip packaging structure of a first embodiment of the present invention;

FIG. 4a is a cross-sectional view of a transparent glue layer in the first embodiment of the present invention;

FIG. 4b is a cross-sectional view of another transparent glue layer in the first embodiment of the present invention;

FIG. 4c is a cross-sectional view of further another transparent glue layer in the first embodiment of the present invention;

FIG. 5 is a cross-sectional view of an optical sensing chip packaging structure of a second embodiment of the present invention;

FIG. 6 is a cross-sectional view of an optical sensing chip packaging structure of a third embodiment of the present invention;

FIG. 7 is a cross-sectional view of an optical sensing chip packaging structure of a fourth embodiment of the present invention; and

FIG. 8 is a cross-sectional view of an optical sensing chip packaging structure of a fifth embodiment of the present invention.

FIG. 9 is a cross-sectional view of an optical sensing chip packaging structure of a sixth embodiment of the present invention.

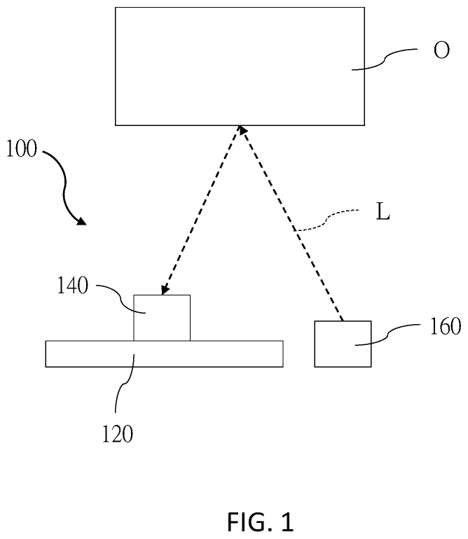

### DETAILED DESCRIPTION OF THE INVENTION

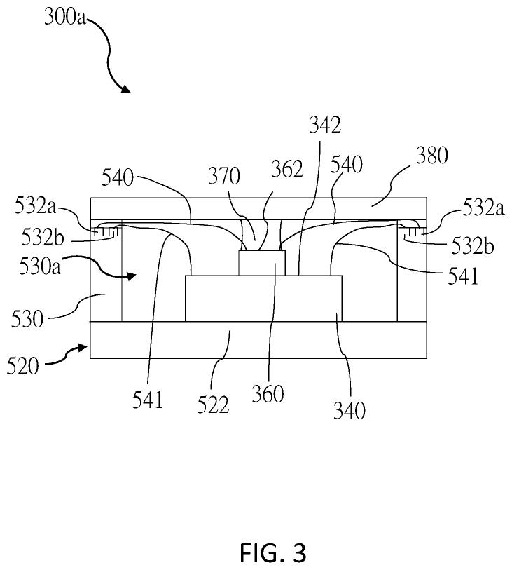

As illustrated in FIG. 3, an optical sensing chip packaging structure 300a of the first embodiment of the present invention includes a substrate 520, an optical sensing member 340, a light emitting member 360, a transparent glue layer 370 and a transparent cover plate 380. In the first embodiment of the present invention, the substrate 520 could be a circuit substrate; the optical sensing member 340 is positioned on the substrate 520, and is electrically connected to the substrate 520.

The light emitting member 360 is positioned on the optical sensing member 340, and is electrically connected to the substrate 520 or the optical sensing member 340. In the first embodiment of the present invention, the light emitting member 360 has a light emitting surface 362, and the optical sensing member 340 is adapted to sense light emitted from the light emitting member 360. In one purpose of the present invention, the optical sensing chip packaging structure 300a can be adapted to sense an object which is in front of the optical sensing chip packaging structure 300a or not. The optical sensing chip packaging structure 300a can be used as a linear scale or a servo motor to detect an object which is moving relative to the optical sensing chip packaging structure 300a or not. In the first embodiment of the present invention, the light emitting member 360 is a spot light source, such as a light emitting diode or a laser source, but is not limited thereto. In the first embodiment of the present invention, the light emitting angle θ of the light emitting member 360 is less than or equal to 150 degree. In addition, in the first embodiment of the present invention, the light emitting surface 362 of the light emitting member 360 and a optical sensing surface 342 of the optical sensing member 340 are substantially in the same direction, and therefore when light emitted from the light emitting surface 362 of the light emitting member 360 is reflected by an object, an angle between the incident light and the reflected light could be as smaller as possible in order to provide a more precise measuring value.

The transparent glue layer 370 is positioned on the light emitting member 360, and contacts and covers the light emitting surface 362, in order to prevent the light emitting surface 362 of the light emitting member 360 from being covered by dust or dirt in air. In the first embodiment of the present invention, a material of the transparent glue layer 370 includes silicone, acrylic glue or a combination thereof, but is not limited thereto.

In the first embodiment of the present invention, as shown in FIG. 3, the substrate 520 of the optical sensing chip packaging structure 300a includes a bottom wall 522 and side walls 530, wherein the bottom wall 522 and the side walls 530 are connected to form an accommodating space 530a. In the first embodiment of the present invention, the bonded points 532a, 532b are positioned on the top of the side walls 530. The optical sensing member 340, the light emitting member 360 and the transparent glue layer 370 are positioned in the accommodating space 530a, and the transparent cover plate 380 is sealed to cover the substrate 520. The light emitting member 360 is connected to a conductive wire 540, and one end of the conductive wire 540 is connected to the light emitting member 360 while the other end thereof is connected to the bonded points 532a, whereby the light emitting member 360 is electrically connected to the substrate 520. Furthermore, the optical sensing member 340 is connected to a conductive wire 541, and one end of the conductive wire 541 is connected to the optical sensing member 340 while the other end thereof is connected to the bonded points 532b, whereby the optical sensing member 340 is electrically connected to the substrate 520. In the first embodiment of the present invention, part of the conductive wire 540 is covered by the transparent glue layer 370.

The transparent cover plate 380 is positioned on the transparent glue layer 370, and the transparent cover plate 380 could directly or indirectly contact the transparent glue layer 370; in the present embodiment, the transparent cover plate 380 directly contacts the transparent glue layer 370.

In embodiments of the present invention, a difference between refractive indexes of the transparent glue layer 370 and the transparent cover plate 380 is less than 0.5; for example, when the material of the transparent glue layer 370 is silicone or acrylic glue, the refractive index of the transparent glue layer 370 is about 1.4; when the material of the transparent cover plate 380 is glass, the refractive index of the transparent cover plate 380 is about 1.5. In one preferred embodiment, a refractive index of the transparent glue layer is substantially the same as that of the transparent cover plate; for example, when the material of the transparent glue layer 370 is silicone, and the material of the transparent cover plate 380 is acrylic material, the refractive indexes of the transparent glue layer 370 and the transparent cover plate 380 are about 1.4. In addition, for difference between refractive indexes of the transparent glue layer 370 and the transparent cover plate 380 is less than 0.5, or the refractive indexes of the transparent glue layer 370 and the transparent cover plate 380 are substantially the same as each other, an interface between the transparent glue layer 370 and the transparent cover plate 380 is less than 4%, and is preferably less than 2% when the transparent glue layer 370 and the transparent cover plate 380 directly contact each other.

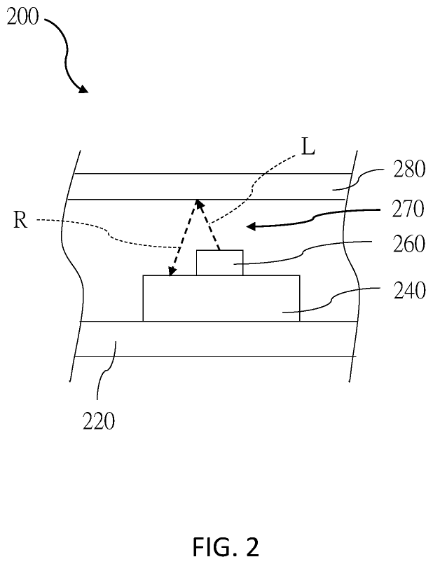

Compared to a reflectivity of the conventional optical sensing chip packaging structure 200 in FIG. 2, which is about 8%, the optical sensing chip packaging structure 300a provided in the present embodiment of the present invention could have a less reflectivity while the transparent cover plate 380 directly or indirectly contacts the transparent glue layer 370. Furthermore, the light path of the optical sensing chip packaging structure 300a would not be changed, for the difference between refractive indexes of the transparent glue layer 370 and the transparent cover plate 380 is too large, so that the optical sensing chip packaging structure 300a provided in the present embodiment of the present invention could improve the noise issue of the conventional the optical sensing chip packaging structure 200, and could provide a greater resolution and a greater accuracy. It is worthy to note that, there is no air bubble in the transparent glue layer 370, whereby to prevent from light refraction in the transparent glue layer 370.

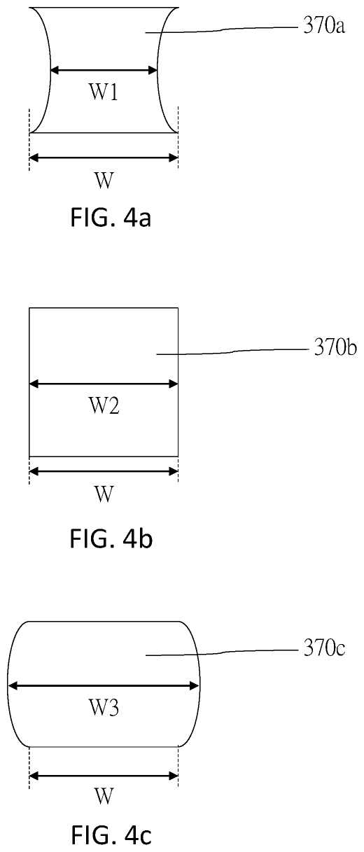

In the first to the fifth embodiments of the present invention, the transparent glue layer 370 could have a plurality shapes as shown in FIG. 4a, FIG. 4b and FIG. 4c. In FIG. 4a, the transparent glue layer 370a has a top and bottom width W and a middle width W1, wherein W is greater than W1. In FIG. 4b, the transparent glue layer 370b has a top and bottom width W and a middle width W2, wherein W is equal to W2. In FIG. 4c, the transparent glue layer 370c has a top and bottom width W and a middle width W3, wherein W is less than W3. It is worthy to mention that, compared to the transparent glue layers 370b, 370c, the transparent glue layer 370a has the greatest connection strength to the light emitting member 360 and the transparent cover plate 380, and would not affect the optical sensing efficiency of the optical sensing member 340. It is preferred that, the transparent glue layers 370a, 370b, 370c are only positioned in a normal projection range of the light emitting member 360, and are not over the normal projection range of the light emitting member 360, so as to prevent the optical sensing surface 342 of the optical sensing member 340 from being covered.

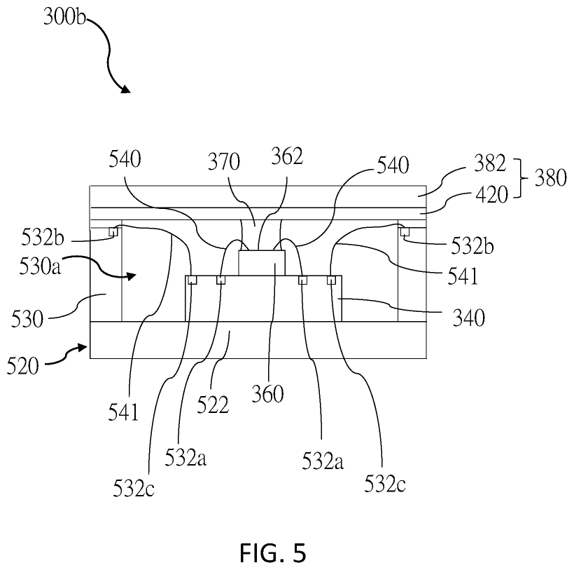

As illustrated in FIG. 5, an optical sensing chip packaging structure 300b of the second embodiment of the present invention includes the transparent cover plate 380 including a first anti-reflection layer 420. The first anti-reflection layer 420 is coated on a bottom surface of a transparent plate 382 of the transparent cover plate 380, whereby the first anti-reflection layer 420 faces the transparent glue layer 370, and the transparent glue layer 370 directly contacts the first anti-reflection layer 420; whereby, the transparent glue layer 370 indirectly contacts the transparent plate 382 through the first anti-reflection layer 420.

In the second embodiment of the present invention, as shown in FIG. 5, the substrate 520 of the optical sensing chip packaging structure 300b includes a bottom wall 522 and side walls 530, wherein the bottom wall 522 and the side walls 530 are connected to form an accommodating space 530a. In the second embodiment of the present invention, the bonded points 532b are positioned on the top of the side walls 530. The optical sensing member 340, the light emitting member 360 and the transparent glue layer 370 are positioned in the accommodating space 530a, and the transparent cover plate 380 is sealed to cover the substrate 520. The light emitting member 360 is connected to a conductive wire 540, and one end of the conductive wire 540 is connected to the light emitting member 360 while the other end thereof is connected to the bonded points 532a, and the bonded points 532a is located on the optical sensing member 340, whereby the light emitting member 360 is electrically connected to the optical sensing member 340. Furthermore, the optical sensing member 340 is connected to a conductive wire 541, and one end of the conductive wire 541 is connected to the bonded points 532c of the optical sensing member 340 while the other end thereof is connected to the bonded points 532b, whereby the optical sensing member 340 is electrically connected to the substrate 520. In the second embodiment of the present invention, part of the conductive wire 540 is covered by the transparent glue layer 370.

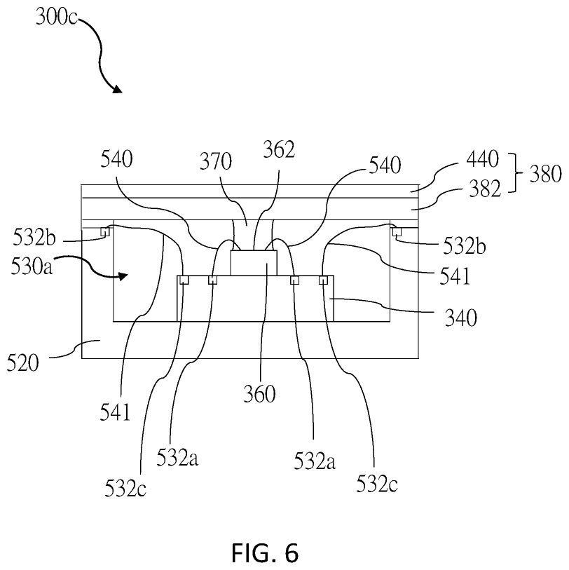

As illustrated in FIG. 6, an optical sensing chip packaging structure 300c of the third embodiment of the present invention includes the transparent cover plate 380 including a second anti-reflection layer 440. The second anti-reflection layer 440 is coated on a top surface of a transparent plate 382 of the transparent cover plate 380, whereby the second anti-reflection layer 440 is back to the transparent glue layer 370. In practice, the transparent plate 382 could be individually coated the first anti-reflection layer 420 and the second anti-reflection layer 440 on the bottom surface and the top surface of the transparent plate 382. With the arrangements of the first anti-reflection layer 420 and the second anti-reflection layer 440, the reflectivity of the transparent cover plate 380 of the optical sensing chip packaging structure 300c could be further reduced, whereby to provide a greater resolution and a greater accuracy.

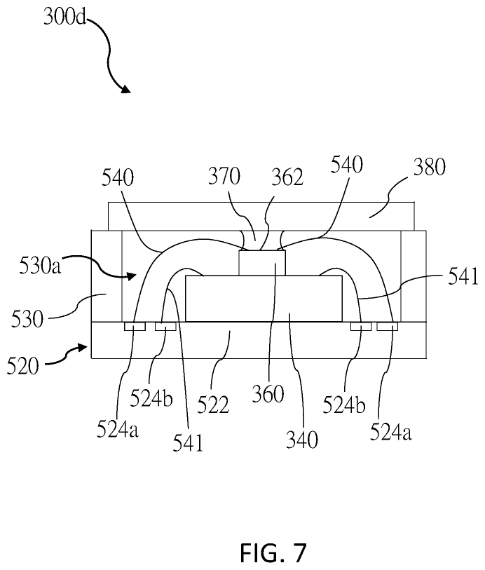

As illustrated in FIG. 7, an optical sensing chip packaging structure 300d of the fourth embodiment of the present invention includes the substrate 520 including a bottom wall 522 and side walls 530, wherein the bottom wall 522 and the side walls 530 are connected to form an accommodating space 530a. In the fourth embodiment of the present invention, the optical sensing member 340, the light emitting member 360 and the transparent glue layer 370 are positioned in the accommodating space 530a, and the transparent cover plate 380 is sealed to cover the side walls 530 of the substrate 520. The bottom wall 522 includes bonded points 524a, 524b. In the fourth embodiment of the present invention, the optical sensing member 340 is connected to a conductive wire 541, and one end of the conductive wire 541 is connected to the optical sensing member 340 while the other end thereof is connected to the bonded points 524b, whereby the optical sensing member 340 is electrically connected to the substrate 520. The light emitting member 360 is connected to a conductive wire 540, and one end of the conductive wire 540 is connected to the light emitting member 360 while the other end thereof is connected to the bonded points 524a, whereby the light emitting member 360 is electrically connected to the substrate 520.

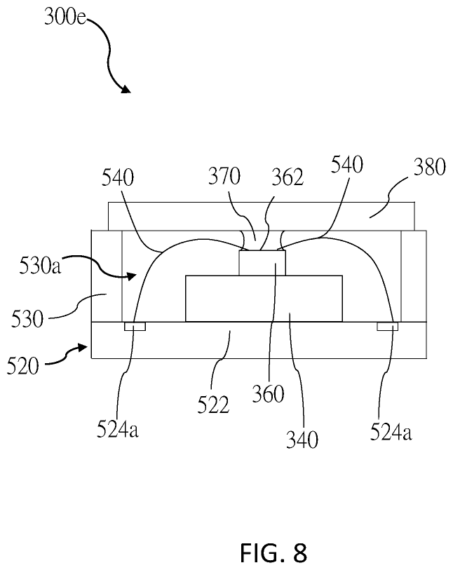

As illustrated in FIG. 8, an optical sensing chip packaging structure 300e of the fifth embodiment of the present invention includes the substrate 520 including a bottom wall 522 and side walls 530, wherein the bottom wall 522 and the side walls 530 are connected to form an accommodating space 530a. In the fifth embodiment of the present invention, the optical sensing member 340, the light emitting member 360 and the transparent glue layer 370 are positioned in the accommodating space 530a, and the transparent cover plate 380 is sealed to cover the side walls 530 of the substrate 520. The bottom wall 522 includes bonded points 524a. In the fifth embodiment of the present invention, the light emitting member 360 is connected to a conductive wire 540, and one end of the conductive wire 540 is connected to the light emitting member 360 while the other end thereof is connected to the bonded points 524a, whereby the light emitting member 360 is electrically connected to the substrate 520. In the fifth embodiment of the present invention, the optical sensing member 340 is a flip chip which could be electrically connected to the substrate 520 without additional conductive wire.

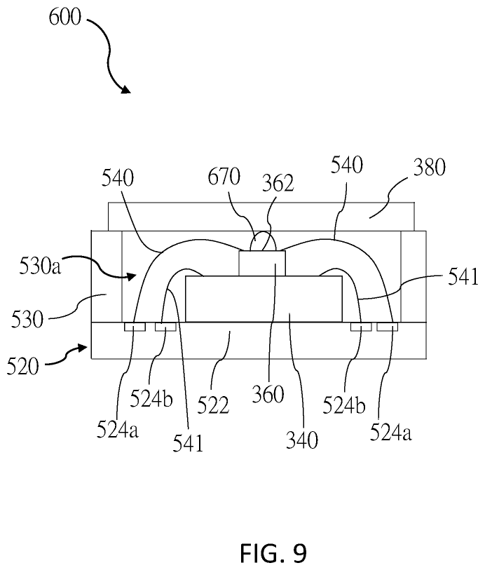

As illustrated in FIG. 9, an optical sensing chip packaging structure 600 of the sixth embodiment of the present invention includes a substrate 520, an optical sensing member 340, a light emitting member 360, a transparent focusing lens 670 and a transparent cover plate 380. In the sixth embodiment of the present invention, the substrate 520 could be a circuit substrate; the optical sensing member 340 is positioned on the substrate 520, and is electrically connected to the substrate 520.

The light emitting member 360 is positioned on the optical sensing member 340. In the sixth embodiment of the present invention, the light emitting member 360 has a light emitting surface 362, and the optical sensing member 340 is adapted to sense light emitted from the light emitting member 360.

The transparent focusing lens 670 is positioned on the light emitting member 360, and contacts and covers the light emitting surface 362, in order to prevent the light emitting surface 362 of the light emitting member 360 from being covered by dust or dirt in air. In the sixth embodiment of the present invention, the light emitting angle θ of the light emitting member 360 is less than or equal to 150 degree. Further, the transparent focusing lens 670 is used to make scattered lights from the light emitting member changing to parallel lights, whereby to reduce the light noise and to reduce the light energy loss.

In the sixth embodiment of the present invention, as shown in FIG. 9, the optical sensing chip packaging structure 600 includes the substrate 520 including a bottom wall 522 and side walls 530, wherein the bottom wall 522 and the side walls 530 are connected to form an accommodating space 530a. In the sixth embodiment of the present invention, the optical sensing member 340, the light emitting member 360 and the transparent focusing lens 670 are positioned in the accommodating space 530a, and the transparent cover plate 380 is sealed to cover the substrate 520. In the sixth embodiment of the present invention, the transparent plate could contact or not contact the transparent focusing lens 670. In the sixth embodiment of the present invention, the light emitting member 360 is connected to a conductive wire 540, and one end of the conductive wire 540 is connected to the light emitting member 360 while the other end thereof is connected to the bonded points 524a, whereby the light emitting member 360 is electrically connected to the substrate 520. Furthermore, the optical sensing member 340 is connected to a conductive wire 541, and one end of the conductive wire 541 is connected to the optical sensing member 340 while the other end thereof is connected to the bonded points 524b, whereby the optical sensing member 340 is electrically connected to the substrate 520.

According to embodiments of the present invention, with the aforementioned design, the transparent glue layer contacts the light emitting surface of the light emitting member, and contacts the transparent cover plate, wherein the light is emitted from the light emitting surface through the transparent glue layer and the transparent cover plate, and there is no air gap between the transparent glue layer and the transparent cover plate, so that the light reflection of the transparent cover plate could be reduced, and the light energy loss by refraction could be reduced. In addition, while the transparent focusing lens is positioned on the light emitting member, and contacts and covers the light emitting surface, it could prevent the light emitting surface of the light emitting member from be covered by dust or dirt in air. Further, the transparent focusing lens is used to make scattered lights from the light emitting member changing to parallel lights, whereby to reduce the light noise and to reduce the light energy loss.

It must be pointed out that the embodiments described above are only some preferred embodiments of the present invention. All equivalent structures which employ the concepts disclosed in this specification and the appended claims should fall within the scope of the present invention.

What is claimed is:

1. An optical sensing chip packaging structure, comprising:
a substrate;
an optical sensing member positioned on and electrically connected to the substrate;
a light emitting member positioned on the optical sensing member, and electrically connected to the substrate or the optical sensing member, wherein the light emitting member has a light emitting surface;
a transparent glue layer positioned on the light emitting member, and contacting and covering the light emitting surface; and
a transparent cover plate positioned on the transparent glue layer, wherein the transparent cover plate contacts the transparent glue layer.

2. The optical sensing chip packaging structure of claim 1, wherein the transparent cover plate directly contacts the transparent glue layer.

3. The optical sensing chip packaging structure of claim 2, wherein a refractive index of the transparent glue layer is substantially the same as that of the transparent cover plate.

4. The optical sensing chip packaging structure of claim 1, wherein the transparent cover plate further comprises a first anti-reflection layer facing the transparent glue layer, and the transparent glue layer contacts the first anti-reflection layer.

5. The optical sensing chip packaging structure of claim 4, wherein a refractive index of the transparent glue layer is substantially the same as that of the transparent cover plate.

6. The optical sensing chip packaging structure of claim 2, wherein an interface between the transparent glue layer and the transparent cover plate has a reflectivity which is less than 4%.

7. The optical sensing chip packaging structure of claim 1, wherein a material of the transparent glue layer comprises silicone, acrylic glue or a combination thereof.

8. The optical sensing chip packaging structure of claim 1, wherein the transparent cover plate further comprises a second anti-reflection layer which is back to the transparent glue layer.

9. The optical sensing chip packaging structure of claim 1, wherein the light emitting member is a spot light source, and a light emitting angle of the spot light source is less than or equal to 150 degree.

10. The optical sensing chip packaging structure of claim 1, wherein a difference between refractive indexes of the transparent glue layer and the transparent cover plate is less than 0.5.

11. The optical sensing chip packaging structure of claim 1, wherein the light emitting member is connected to a conductive wire, and one end of the conductive wire is connected to the optical sensing member, whereby the light emitting member is electrically connected to the optical sensing member.

12. The optical sensing chip packaging structure of claim 11, wherein part of the conductive wire is covered by the transparent glue layer.

13. The optical sensing chip packaging structure of claim 1, wherein the light emitting member is connected to a conductive wire, and one end of the conductive wire is connected to the substrate, whereby the light emitting member is electrically connected to the substrate.

14. The optical sensing chip packaging structure of claim 13, wherein part of the conductive wire is covered by the transparent glue layer.

15. The optical sensing chip packaging structure of claim 1, wherein no bubble is in the transparent glue layer.

16. The optical sensing chip packaging structure of claim 1, wherein the transparent glue layer does not contact the optical sensing member and the substrate.

17. The optical sensing chip packaging structure of claim 1, wherein the transparent glue layer is only positioned in a normal projection range of the light emitting member.

18. An optical sensing chip packaging structure, comprising:
a substrate;
an optical sensing member positioned on and electrically connected to the substrate;
a light emitting member positioned on the optical sensing member, and electrically connected to the substrate or the optical sensing member, wherein the light emitting member has a light emitting surface;
a transparent focusing lens positioned on the light emitting member, and contacting and covering the light emitting surface; and
a transparent cover plate positioned on the transparent focusing lens.
